(19) United States
(12) Patent Application Publication
(10) Pub. No.: US 2014/0117525 A1
(43) Pub. Date: May 1, 2014

(54) POWER MODULE PACKAGE AND METHOD OF MANUFACTURING THE SAME

(71) Applicant: Samsung Electro-Mechanics Co., Ltd., Suwon (KR)

(72) Inventors: Young Ki Lee, Suwon (KR); Kwang Soo Kim, Suwon (KR); Young Hoon Kwak, Suwon (KR); Sun Woo Yun, Suwon (KR)

(73) Assignee: Samsung Electro-Mechanics Co., Ltd., Suwon (KR)

(21) Appl. No.: 14/065,039

(22) Filed: Oct. 28, 2013

(30) Foreign Application Priority Data
Oct. 29, 2012 (KR) 10-2012-0120392

(51) Int. Cl. H01L 23/495; H01L 21/50

(52) U.S. Cl. CPC H01L 23/495; H01L 21/50
USPC 257/676; 438/123

(57) ABSTRACT

Disclosed herein is a power module package including: a base substrate; a metal layer including a circuit pattern and a connection pad formed on the base substrate; a semiconductor device including a plurality of electrodes mounted on the circuit pattern of the metal layer; and a plurality of lead frames formed on the connection pad of the metal layer and respectively connected to the plurality of electrodes of the semiconductor device.

### CROSS REFERENCE TO RELATED APPLICATION

This application claims the benefit of Korean Patent Application No. 10-2012-0120392, filed on Oct. 29, 2012, entitled “Power Module Package and Method of Manufacturing the Same”, which is hereby incorporated by reference in its entirety into this application.

### BACKGROUND OF THE INVENTION

1. Technical Field

The present invention relates to a power module package and a manufacturing method thereof.

2. Description of the Related Art

Underground resources are limited, whereas an amount of used energy tends to increase every year. Accordingly, much interest and efforts have been devoted to development of alternative energy worldwide. Such efforts lead to development of technology that yields high efficiency at low energy.

Meanwhile, power modules, including Patent Document 1, are largely classified into inverters, converters, and motor driving power modules, have a variety of shapes according to their uses, and also tend to have gradually increasing amounts of use.

A given industrial high capacity power module is applied in a case shape. If the power module is lighter, thinner, shorter, and smaller, it may be supplied at a lower price.

However, in order to realize the above-described matters of the power module, there is need to increase productivity.

[Prior Art Document]

[Patent Document]

(Patent Document 1) U.S. Pat. No. 7,208,819 B

### SUMMARY OF THE INVENTION

The present invention has been made in an effort to provide a power module package for simplifying an electrical or physical connection between a semiconductor device and a substrate or a lead frame and the semiconductor device and simultaneously enhancing processing reliability and a manufacturing method thereof.

According to a first preferred embodiment of the present invention, there is provided a method of manufacturing a power module package, the method including: preparing a base substrate; forming a metal layer including a circuit pattern and a connection pad on the base substrate; forming a plurality of lead frames having one side connected onto the connection pad of the metal layer and another side spaced apart from the circuit pattern of the metal layer to an upper side with respect to a thickness direction of the base substrate; and moving a semiconductor device including a plurality of electrodes in a horizontal direction that is a lengthwise direction of the base substrate and mounting the semiconductor device between the circuit pattern of the metal layer and another side of the plurality of lead frames, wherein each of the plurality of lead frames is connected to each of the plurality of electrodes of the semiconductor device.

In the forming of the plurality of lead frames, the plurality of lead frames may be formed having different lengths with respect to the lengthwise direction of the base substrate according to a location of each contacting electrode.

In the forming of the plurality of lead frames, the plurality of lead frames may be formed in a structure in which an area contacting each of the plurality of electrodes is bent in a direction of a corresponding electrode.

The forming of the metal layer may include forming a bonding layer groove having a predetermined depth from a surface in which the semiconductor device is mounted in the circuit pattern of the metal layer.

The method may further include: forming a first conductive bonding layer in the bonding layer groove.

In a case where the first conductive bonding layer has a preform shape formed having the same size as the bonding layer groove, in the forming of the first conductive bonding layer, the first conductive bonding layer in the preform shape may be arranged in the bonding layer groove.

The method may further include: before the moving and mounting of the semiconductor device, forming second conductive bonding layers among the plurality of electrodes of the semiconductor device in contacting areas of the plurality of lead frames, respectively.

The method may further include: after the moving and mounting of the semiconductor device, coupling the first conductive bonding layer and the semiconductor device to each other through a reflow process, and coupling the second conductive bonding layers and the plurality of electrodes to each other.

The method may further include: after the moving and mounting of the semiconductor device, forming a housing to surround external circumferential surfaces and side surfaces of the base substrate and the metal layer.

The method may further include: after the forming of the housing, forming a molding member inside the housing to surround upper surfaces of the plurality of lead frames.

The method may further include: after the moving and mounting of the semiconductor device, forming a molding member to surround the base substrate, the metal layer, the semiconductor device, and the lead frames.

According to a second preferred embodiment of the present invention, there is provided a power module package including: a base substrate; a metal layer including a circuit pattern and a connection pad formed on the base substrate; a semiconductor device including a plurality of electrodes mounted on the circuit pattern of the metal layer; and a plurality of lead frames formed on the connection pad of the metal layer and respectively connected to the plurality of electrodes of the semiconductor device, wherein the plurality of lead frames are formed having different lengths with respect to the lengthwise direction of the base substrate according to a location of each contacting electrode.

The plurality of lead frames may be formed in a structure in which an area contacting each of the plurality of electrodes is bent in a direction of a corresponding electrode.

A bonding layer groove having a predetermined depth from a surface on which the semiconductor device is mounted may be formed in the circuit pattern of the metal layer.

The power module package may include: a first conductive bonding layer formed in the bonding layer groove.

The first conductive bonding layer may be formed of a solder material.

The power module package may further include: second conductive bonding layers formed in contacting areas of the plurality of lead frames and the plurality of electrodes.

The power module package may further include: a housing formed to surround external circumferential surfaces and side surfaces of the base substrate and the metal layer.

The power module package may further include: a molding member formed inside the housing to surround upper surfaces of the plurality of lead frames.

The power module package may further include: a molding member formed to surround the base substrate, the metal layer, the semiconductor device, and the lead frames.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 3 are cross-sectional views for sequentially explaining the process of a method of manufacturing a power module package according to an embodiment of the present invention;

FIG. 4 is an upper plan view of a power module package according to an embodiment of the present invention;

FIG. 5 is a cross-sectional view of a power module package in which a housing is installed according to an embodiment of the present invention; and

FIG. 6 is a cross-sectional view of a power module package in which a molding member is formed according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Method of Manufacturing Power Module Package

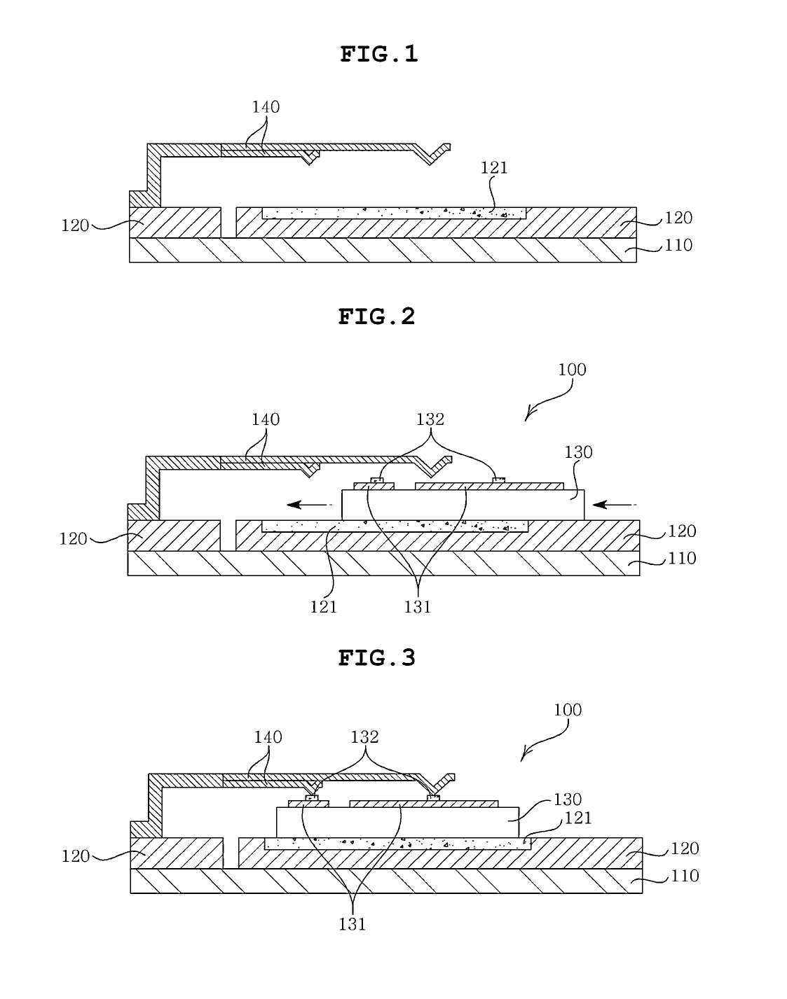

FIGS. 1 to 3 are cross-sectional views for explaining a method of manufacturing a power module package according to an embodiment of the present invention.

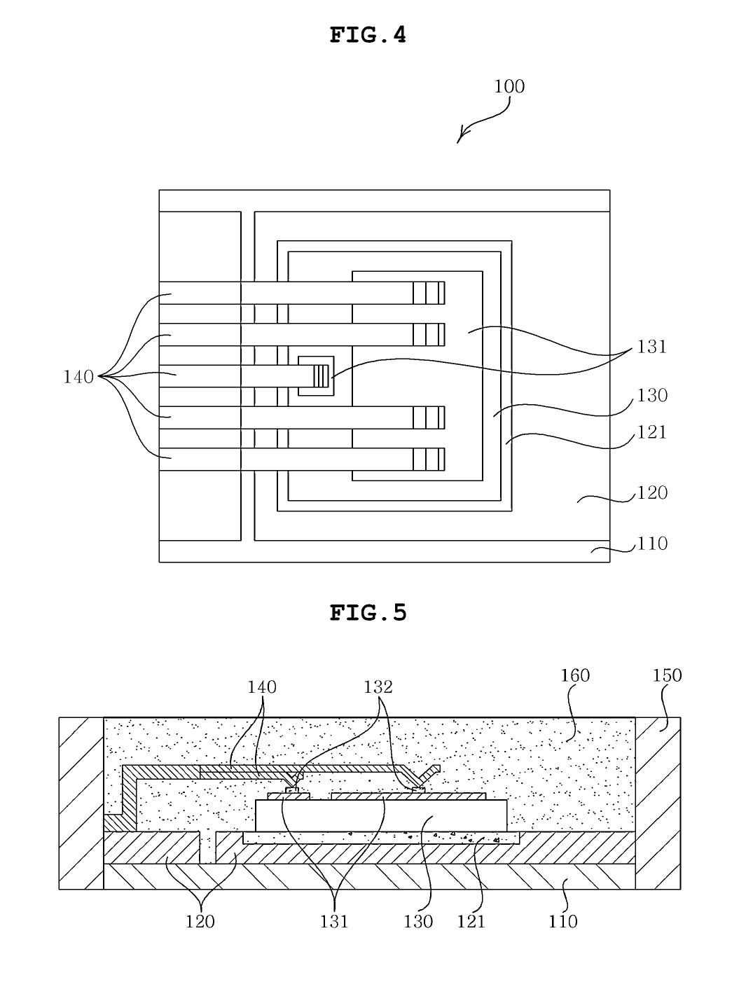

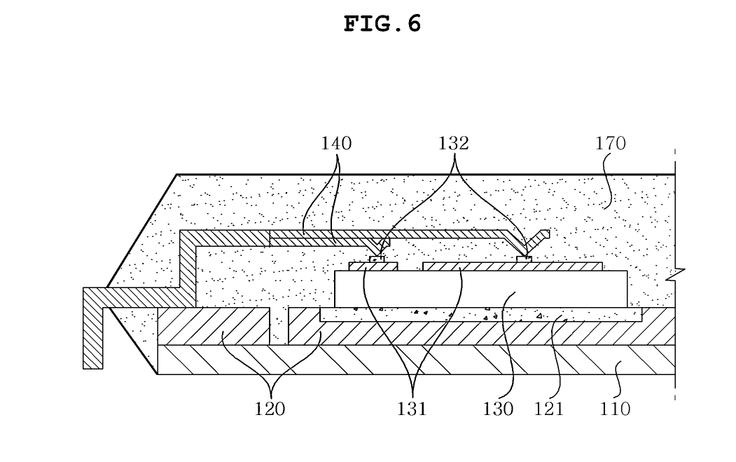

In this regard, the method of manufacturing the power module package will now be described with reference to FIG. 4 that is an upper plan view of a power module package according to an embodiment of the present invention, FIG. 5 that is a cross-sectional view of a power module package in which a housing is installed according to an embodiment of the present invention, and FIG. 6 that is a cross-sectional view of a power module package in which a molding member is formed according to an embodiment of the present invention.

A base substrate 110 may be prepared as shown in FIG. 1.

The base substrate 110 may be a usual insulating layer applied as a core substrate in a printed circuit board (PCB) field or a PCB in which one- or more-inner layer circuit is formed in an insulating layer.

A resin insulating layer may be used as the insulating layer. Thermosetting resin like epoxy resin, thermoplastic resin like polyimide, resin, for example, prepreg, in which glass fiber or a reinforcing material such as inorganic fillers is impregnated into the thermosetting resin and the thermoplastic resin, or thermosetting resin and/or photocurable resin but the present invention is not limited thereto.

Although not shown, an additional element such as a heat sink formed of a metallic material may be further formed in a lower portion of the base substrate 110 but the present invention is not limited thereto.

As shown in FIG. 1, a metal layer 120 including a circuit pattern and a connection pad may be formed on the base substrate 110.

In this regard, the circuit pattern of the metal layer 120 is classified as a metal layer corresponding to an area on which a semiconductor device 130 is to be mounted, and the connection pad thereof is classified as a metal layer corresponding to an area to a lead frame 140 is to be coupled.

In an operation of forming the metal layer 120, as shown in FIG. 1, a bonding layer groove (not shown) having a predetermined depth from a surface on which the semiconductor device is mounted may be formed in the circuit pattern of the metal layer 120.

As shown in FIG. 1, the bonding layer groove may be in a groove shape having the predetermined depth with respect to a thickness direction of a substrate.

Next, as shown in FIG. 1, a first conductive bonding layer 121 may be formed in the bonding layer groove.

In this regard, the first conductive bonding layer 121 may be formed of a solder material but the present invention is not limited thereto.

Meanwhile, in a case where the first conductive bonding layer 121 has a preform shape formed having the same size as the bonding layer groove, an operation of forming the first conductive bonding layer may be an operation of arranging the first conductive bonding layer 121 in the preform shape in the bonding layer groove.

In more detail, the first conductive bonding layer 121 may have a preform shape in a solid state. In this case, the first conductive bonding layer 121 in the preform shape previously molded corresponding to the size of the bonding layer groove may be coupled through a process of arranging the first conductive bonding layer 121 in the bonding layer groove.

In this regard, the first conductive bonding layer 121 may be firmly coupled to the bonding layer groove after changing to a melting state through a subsequent reflow process and then changing to a solid state.

Further, the first conductive bonding layer 121 may be a conductive bonding film form.

Next, as shown in FIG. 1, a plurality of lead frames 140 may be formed in such a manner that one side is connected onto the connection pad of the metal layer 120 and another side is spaced apart from the circuit pattern of the metal layer 120 to an upper side with respect to the thickness direction of the substrate.

In an operation of forming the plurality of lead frames 140, as shown in FIG. 4, the plurality of lead frames 140 may be formed having different lengths with respect to a lengthwise direction of the substrate according to a location of each contacting electrode but the present invention is not limited thereto.

Further, in the operation of forming the plurality of lead frames 140, as shown in FIG. 3, the plurality of lead frames 140 may be formed in a structure in which an area contacting each of a plurality of electrodes 131 is bent in a direction of a corresponding electrode.

In this regard, due to the bent structure of the lead frames 140, the lead frames 140 may be electrically connected to the semiconductor device 130 directly, and accordingly, an additional process such as wire bonding may be skipped, thereby expecting an effect of simplifying a manufacturing process.

Next, as shown in FIGS. 2 and 3, the semiconductor device 130 including the plurality of electrodes 131 between the circuit pattern of the metal layer 120 and another side of the lead frames is mounted by moving in a horizontal direction that is the lengthwise direction of the substrate.

In this regard, each of the plurality of lead frames 140 may be connected to each of the plurality of electrodes 131 of the semiconductor device 130.

Meanwhile, as shown in FIG. 2, before an operation of moving and mounting the semiconductor device 130, second conductive bonding layers 132 among the plurality of electrodes 131 of the semiconductor device 130 may be formed in contacting areas of the plurality of lead frames 140, respectively.

In this regard, the second conductive bonding layers 132 may be formed of solder materials but the present invention is not limited thereto. The second conductive bonding layers 132 may be formed of all conductive materials as long as the lead frames and the electrodes may be coupled to each other.

As shown in FIG. 2, although the second conductive bonding layers 132 can be formed as additional layers, the present invention is not limited thereto, and they can be formed by being coated on the plurality of electrodes 131.

Next, although not shown, after the operation of moving and mounting the semiconductor device 130, the first conductive bonding layer 121 and the semiconductor device 130 are coupled to each other through a reflow process, and the second conductive bonding layers 132 and the plurality of electrodes 131 may be coupled to each other.

That is, a power module package 100 according to an embodiment of the present invention may couple upper and lower surfaces of the semiconductor device 130 to the lead frames and the metal layer, respectively, through the reflow process, thereby simplifying a process as well as enhancing coupling reliability between elements of a product.

Next, as shown in FIG. 5, after the operation of moving and mounting the semiconductor device 130, a housing 150 may be formed to surround external circumferential surfaces and side surfaces of the base substrate 110 and the metal layer 120.

Next, as shown in FIG. 5, after the operation of forming the housing 150, a molding member 160 may be formed inside the housing 150 to surround upper surfaces of the plurality of lead frames 140.

Meanwhile, as shown in FIG. 6, after the operation of moving and mounting the semiconductor device 130, a molding member 170 can be formed to surround the base substrate 110, the metal layer 120, the semiconductor device 130, and the lead frames 140.

As shown in FIG. 6, this surrounds elements of the power module package 100 only by using the molding member 170 without applying the housing 150.

An external electrical connection of the power module package according to an embodiment of the present invention is not wire bonding but may physically contact the lead frames that are already structurally connected to the outside and an electrode of the semiconductor device, as shown in FIG. 3.

Also, according to an embodiment of the present invention, the semiconductor device is not conventionally mounted on a surface but may be mounted on the circuit pattern of the metal layer by horizontally moving, and thus a location of the semiconductor device is more freely changed during a process of manufacturing the power module package, thereby expecting an effect of enhancing a design freedom of a product.

Power Module Package

FIG. 4 is an upper plan view of the power module package 100 according to an embodiment of the present invention. FIG. 5 is a cross-sectional view of the power module package 100 in which the housing 150 is installed according to an embodiment of the present invention. FIG. 6 is a cross-sectional view of the power module package 100 in which the molding member 170 is formed according to an embodiment of the present invention.

In this regard, the power module package will now be described with reference to FIGS. 1 to 3 that are cross-sectional views for sequentially explaining the process of a method of manufacturing a power module package according to an embodiment of the present invention.

As shown in FIG. 3, the power module package 100 according to an embodiment of the present invention may include the base substrate 110, the metal layer 120 including a circuit pattern and a connection pad that are formed on the base substrate 110, the semiconductor device 130 including a plurality of electrodes mounted on the circuit pattern of the metal layer 120, and the plurality of lead frames 140 formed on the connection pad of the metal layer 120 and respectively connected to the plurality of electrodes 131 of the semiconductor device 130.

In this regard, as shown in FIG. 4, the plurality of lead frames 140 may be formed having different lengths with respect to a lengthwise direction of a substrate according to a location of each contacting electrode but the present invention is not limited thereto.

Also, the plurality of lead frames 140 may be formed in a structure in which an area contacting each of the plurality of electrodes 131 is bent in a direction of a corresponding electrode.

As shown in FIG. 3, a bonding layer groove (not shown) having a predetermined depth from a surface on which a semiconductor device is mounted may be formed in the circuit pattern of the to metal layer 120.

The power module package 100 may further include the first conductive bonding layer 121 formed in the bonding layer groove.

In this regard, the first conductive bonding layer 121 may be formed of a solder material.

The first conductive bonding layer 121 may have a preform shape in a solid state. In this case, the first conductive bonding layer 121 in the preform shape previously molded corresponding to the size of the bonding layer groove may be coupled through a process of arranging the first conductive bonding layer 121 in the bonding layer groove.

In this regard, the first conductive bonding layer 121 may be firmly coupled to the bonding layer groove after changing to a melting state through a subsequent reflow process and then changing to a solid state.

Further, the first conductive bonding layer 121 may be a conductive bonding film form.

Also, as shown in FIG. 3, the power module package 100 may further include the second conductive bonding layers 132 formed in contacting areas of the plurality of lead frames 140 and a plurality of electrodes.

Meanwhile, as shown in FIG. 5, the power module package 100 may further include the housing 150 formed to surround external circumferential surfaces and side surfaces of the base substrate 110 and the metal layer 120.

Also, as shown in FIG. 5, the power module package 100 may further include the molding member 160 formed inside the housing 150 to surround upper surfaces of the plurality of lead frames 140.

Meanwhile, as shown in FIG. 6, the power module package 100 may further include the molding member 170 formed to surround the base substrate 110, the metal layer 120, the semiconductor device 130, and the lead frames 140.

With the power module package and the method of manufacturing the same according to the embodiments of the present invention, after a lead frame having a structure to which a semiconductor device is contactable is first formed on a base substrate in which a metal layer is formed, the semiconductor device is mounted by moving in a horizontal direction, which can skip a wire bonding process, thereby expecting an effect of simplifying a package manufacturing process.

Further, according to the embodiments of the present invention, a lead frame and a semiconductor device are directly connected to each other by omitting a wire for an electrical connection of the semiconductor device of a package, thereby pursuing stability in terms of the electrical connection, and accordingly enhancing reliability of a product.

In addition, according to the embodiments of the present invention, a conductive bonding layer in a preform shape in a slide state is applied between a semiconductor device and a substrate, thereby omitting an additional solder printing process and simplifying a manufacturing process.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method of manufacturing a power module package, the method comprising:
preparing a base substrate;
forming a metal layer including a circuit pattern and a connection pad on the base substrate;
forming a plurality of lead frames having one side connected onto the connection pad of the metal layer and another side spaced apart from the circuit pattern of the metal layer to an upper side with respect to a thickness direction of the base substrate; and
moving a semiconductor device including a plurality of electrodes in a horizontal direction to that is a lengthwise direction of the base substrate and mounting the semiconductor device between the circuit pattern of the metal layer and another side of the plurality of lead frames,
wherein each of the plurality of lead frames is connected to each of the plurality of electrodes of the semiconductor device.

2. The method as set forth in claim 1, wherein, in the forming of the plurality of lead frames, the plurality of lead frames are formed having different lengths with respect to the lengthwise direction of the base substrate according to a location of each contacting electrode.

3. The method as set forth in claim 1, wherein in the forming of the plurality of lead frames, the plurality of lead frames are formed in a structure in which an area contacting each of the plurality of electrodes is bent in a direction of a corresponding electrode.

4. The method as set forth in claim 1, wherein the forming of the metal layer includes forming a bonding layer groove having a predetermined depth from a surface on which the semiconductor device is mounted in the circuit pattern of the metal layer.

5. The method as set forth in claim 4, further comprising forming a first conductive bonding layer in the bonding layer groove.

6. The method as set forth in claim 5, wherein, in a case where the first conductive bonding layer has a preform shape formed having the same size as the bonding layer groove, in the forming of the first conductive bonding layer, the first conductive bonding layer in the preform shape is arranged in the bonding layer groove.

7. The method as set forth in claim 5, further comprising: before the moving and mounting of the semiconductor device, forming second conductive bonding layers among the plurality of electrodes of the semiconductor device in contacting areas of the plurality of lead frames, respectively.

8. The method as set forth in claim 7, further comprising: after the moving and mounting of the semiconductor device, coupling the first conductive bonding layer and the semiconductor device to each other through a reflow process, and coupling the second conductive bonding layers and the plurality of electrodes to each other.

9. The method as set forth in claim 1, further comprising: after the moving and mounting of the semiconductor device, forming a housing to surround external circumferential surfaces and side surfaces of the base substrate and the metal layer.

10. The method as set forth in claim 9, further comprising: after the forming of the housing, forming a molding member inside the housing to surround upper surfaces of the plurality of lead frames.

11. The method as set forth in claim 1, further comprising: after the moving and mounting of the semiconductor device, forming a molding member to surround the base substrate, the metal layer, the semiconductor device, and the lead frames.

12. A power module package comprising:
a base substrate;
a metal layer including a circuit pattern and a connection pad formed on the base substrate;
a semiconductor device including a plurality of electrodes mounted on the circuit pattern of the metal layer; and
a plurality of lead frames formed on the connection pad of the metal layer and respectively connected to the plurality of electrodes of the semiconductor device,
wherein the plurality of lead frames are formed having different lengths with respect to the lengthwise direction of the base substrate according to a location of each contacting electrode.

13. The power module package as set forth in claim 12, wherein the plurality of lead frames are formed in a structure in which an area contacting each of the plurality of electrodes is bent in a direction of a corresponding electrode.

14. The power module package as set forth in claim 12, wherein a bonding layer groove having a predetermined depth from a surface on which the semiconductor device is mounted is formed in the circuit pattern of the metal layer.

15. The power module package as set forth in claim 14, further comprising: a first conductive bonding layer formed in the bonding layer groove.

16. The power module package as set forth in claim 15, wherein the first conductive bonding layer is formed of a solder material.

17. The power module package as set forth in claim 12, further comprising: second conductive bonding layers formed in contacting areas of the plurality of lead frames and the plurality of electrodes.

18. The power module package as set forth in claim 12, further comprising: a housing formed to surround external circumferential surfaces and side surfaces of the base substrate and the metal layer.

19. The power module package as set forth in claim 18, further comprising: a molding member formed inside the housing to surround upper surfaces of the plurality of lead frames.

20. The power module package as set forth in claim 12, further comprising: a molding member formed to surround the base substrate, the metal layer, the semiconductor device, and the lead frames.
